(19) United States
(12) Patent Application Publication
(10) Pub. No.: US 2012/0002381 A1
(43) Pub. Date: Jan. 5, 2012

(54) METHOD FOR MANUFACTURING A LIQUID-TIGHT ELECTRONIC DEVICE, AND LIQUID-TIGHT ELECTRONIC DEVICE

(75) Inventor: Umberto Zanoni, Madone (IT)

(73) Assignee: STMicroelectronics S.r.l., Agrate Brianza (IT)

(21) Appl. No.: 13/172,562

(22) Filed: Jun. 29, 2011

(30) Foreign Application Priority Data
Jun. 30, 2010 (IT) TO2010A000565

(51) Int. Cl. H05K 5/02; H05K 3/00

(52) U.S. Cl. 361/752; 29/829

(57) ABSTRACT

A method for manufacturing a liquid-tight electronic device includes: providing a first printed-circuit board having a first connector; providing a supporting structure having a first opening; forming a first assembly by coupling the supporting structure and the first printed-circuit board in such a way that the first connector extends through the first opening and delimits a bottom gap; and forming a second assembly having a protective shell. The method further includes: depositing a first layer of liquid resin within the bottom gap, and hardening the first layer of liquid resin; depositing a second layer of liquid resin within the second assembly; coupling the first and second assemblies in such a way that the second layer of liquid resin hermetically closes a first interstitial area between the protective shell and the supporting structure; and hardening the second layer of liquid resin.

### BACKGROUND

1. Technical Field

The present disclosure relates to a method for manufacturing a liquid-tight electronic device and to a liquid-tight electronic device.

2. Description of the Related Art

As is known, in some fields of application it is desirable to have available liquid-tight electronic devices, which are able to operate even in the presence of liquids. In particular, this is desired where there is the possibility for a liquid to come into contact with electrical machinery incorporating electronic devices.

In detail, generally the electronic devices comprise respective enclosures, which can be classified, for example, according to the CEI-EN60529/1997 standard that corresponds to the degrees of protection of the enclosures. Once again by way of example, in some fields of application electronic devices have enclosures that are classified, for example, as International Protection (IP) 65, IP66, or IP67, and hence have liquid-tightness, in regard to jets of water, strong jets of water, and effects of temporary immersion, that is certified.

In order to produce liquid-tight electronic devices, it is common to use appropriate gaskets, which are set so as to seal the electronic circuitries contained within the electronic devices.

In particular, it is known to insert, within an electronic device comprising amongst other things a frame and a shell, a gasket, which is precisely set between the frame and the shell. In practice, the gasket is a deformable element, which is inserted between two elements (frame and shell) that are stiffer than the gasket itself and are mechanically coupled to one another. In addition, mechanical coupling between the shell and the frame means that the gasket is subject to a mechanical pressure such as to enable the effective liquid-tightness of the joining region defined by the same frame and shell.

The use of gaskets makes it possible to provide liquid-tight electronic devices; however, it entails certain drawbacks. In fact, in order to guarantee liquid-tightness, it is necessary for the mechanical pressure to which the gasket is subjected to be distributed uniformly along the gasket. In addition, to cause the gasket to be set properly with respect to the frame and shell, it is generally necessary to resort to appropriate alignment elements. In addition, the use of a gasket entails the need to have, within the electronic device, sufficient space for the gasket itself. Finally, the gasket is inevitably subject to processes of ageing and of damage; there hence typically occurs a degradation over time of the liquid-tightness of the electronic device.

It is likewise known that, in some fields of application, it is desirable to have available electronic devices capable of operating also at high temperatures, for example higher than 125° C.

In detail, the maximum operating temperature of a generic electronic device, i.e., the temperature beyond which the electronic device cannot work, because otherwise it might melt, depends upon the maximum operating temperatures of the electronic components present within the same electronic device. In particular, given an electronic device formed by a set of electronic components, the respective maximum operating temperature, also known as “thermal rating”, depends upon the electronic components most sensitive to temperature, i.e., upon the electronic components that are characterized by the lowest maximum operating temperatures.

In order to increase the maximum operating temperature of an electronic device, it is known to equip the electronic components most sensitive to temperature with respective dissipators. Alternatively, instead of the dissipators coupled to individual electronic components, it is known to use a single dissipator for all the electronic components of the electronic device; this dissipator typically has a large surface to dissipate a considerable amount of heat. By way of example, dissipators are known formed by a plurality of cylindrical surfaces, having the function of increasing the thermal dissipation in air by the dissipator itself.

The techniques described enable provision of electronic devices capable of operating also at high temperatures; however, they entail some drawbacks, amongst which, for example, the fact that the electronic devices thus made generally have non-negligible overall dimensions and/or high manufacturing costs.

### BRIEF SUMMARY

Some embodiment of the present disclosure provide a method for manufacturing a liquid-tight electronic device, and a liquid-tight electronic device that will enable the drawbacks of the known art to be at least partially overcome.

According to the disclosure, a method for manufacturing a liquid-tight electronic device, a liquid-tight electronic device, and an electronic system are provided as defined, respectively, in claims 1, 9 and 18.

### BRIEF DESCRIPTION OF THE SEVERAL VIEWS OF THE DRAWINGS

For a better understanding of the disclosure, embodiments thereof are now described, purely by way of non-limiting example and with reference to the attached drawings, wherein:

FIG. 1 shows an exploded view of an electronic device;

FIG. 2 is a schematic illustration of a cross section of the electronic device shown in FIG. 1;

FIGS. 3 and 4 show at an enlarged scale portions of the cross section shown in FIG. 2;

FIG. 5 is a flowchart of operations according to the present method;

FIGS. 6-12 are schematic illustrations of cross sections of assemblies during successive steps of manufacturing of the electronic device shown in FIG. 1;

FIG. 13 is a schematic illustration of a cross section of an electronic device;

FIG. 14 shows a block diagram of an electronic system;

FIGS. 15 and 18 show exploded views of electronic devices;

FIG. 16 is a schematic illustration of a cross section of a thermal shield and of an electromagnetic shield;

FIG. 17 is a schematic illustration of a cross section of an assembly during a step of production of the electronic device shown in FIG. 15; and

FIG. 19 is a schematic and enlarged illustration of a portion of a cross section of an electronic device.

### DETAILED DESCRIPTION

The present method envisages rendering an electronic device liquid-tight by using the so-called “potting” technique, which in turn envisages injecting within the electronic device an impregnating resin, and then cross-linking, i.e., hardening, the injected resin, for example by means of heat.

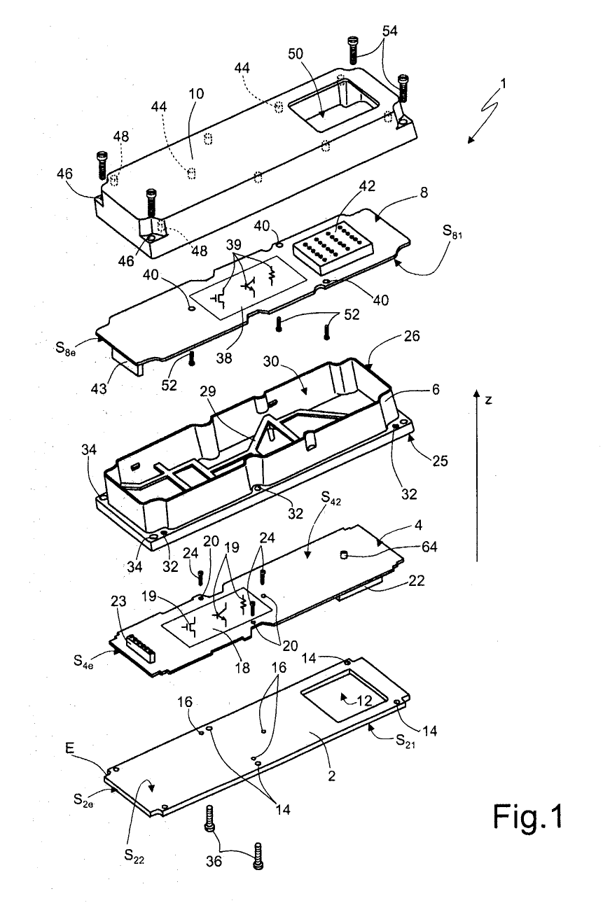

In what follows the present method is described in detail, with reference to the electronic device 1, shown in FIG. 1.

The electronic device 1 comprises a bottom plate 2, a bottom printed-circuit board (bottom PCB) 4, a frame 6, a top printed-circuit board (top PCB) 8, and a top shell 10.

In detail, the bottom plate 2, made for example of copper, has a negligible thickness and has a bottom surface S₂₁, a top surface S₂₂, and a lateral surface S₂ₑ. In addition, the bottom plate 2 has an opening, which in what follows will be referred to as “bottom opening” 12. Moreover, the bottom plate 2 has a plurality of first and second threaded holes, designated respectively by 14 and 16. The first threaded holes 14 are of a through type, whereas the second threaded holes 16 are of a blind type.

The bottom printed-circuit board 4 comprises a first electronic circuit 18, illustrated schematically and formed by a plurality of first electronic components 19, which are also illustrated schematically. Furthermore, the bottom printed-circuit board 4 comprises a plurality of third threaded holes 20 of a through type, bottom connectors 22, and first internal connectors 23. In particular, the bottom connectors 22 are set on a bottom surface S₄₁ of the bottom printed-circuit board 4, facing the bottom plate 2; instead, the first internal connectors 23 are set on a top surface S₄₂ of the bottom printed-circuit board 4, opposite to the bottom surface S₄₁.

In greater detail, the bottom connectors 22 are set so as to extend within the bottom opening 12 of the bottom plate 2. Furthermore, the third threaded holes 20 are set so as to be aligned with respective second threaded holes 16 of the bottom plate 2. The bottom printed-circuit board 4 is then constrained to the bottom plate 2 by means of a plurality of first screws 24, which pass through the second and third threaded holes 16, 20. The frame 6 can be made of plastic material, such as for example polybutylene terephthalate, and has a shape such as to enable mechanical coupling with the bottom plate 2.

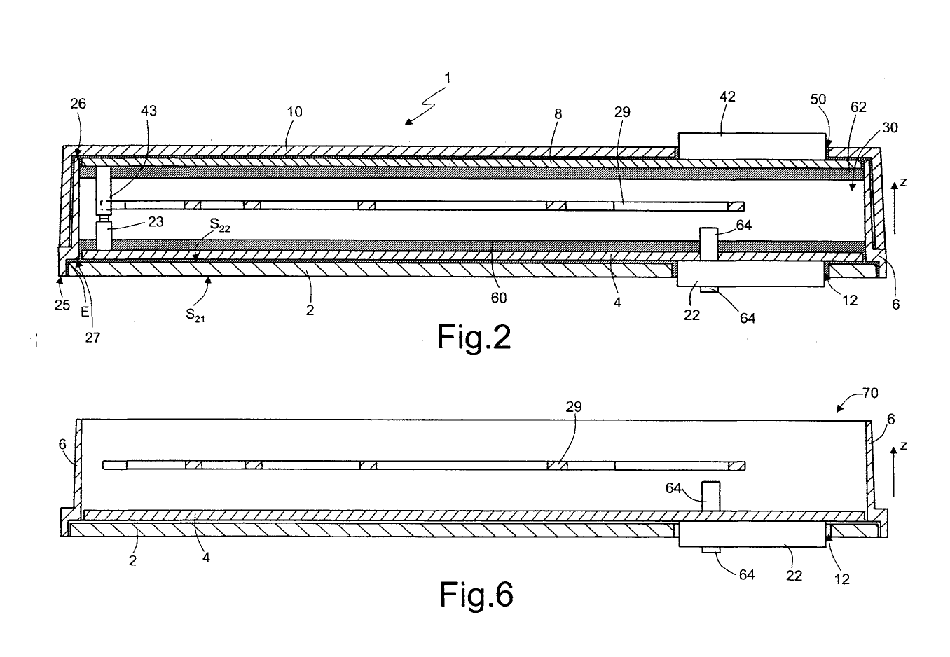

In detail, the frame 6 has a bottom edge 25 and a top edge 26, and defines, in joining the bottom edge 25 to the top edge 26, a shoulder 27 (FIG. 2), which faces, and has a shape complementary to, a sharp edge E of the bottom plate 2, which joins the top surface S₂₂ and the lateral surface S₂ₑ of the same bottom plate 2. Furthermore, the frame 6 forms a plurality of supporting elements 29, of a known type, and defines a cavity 30; also, the frame 6 has a respective plurality of fourth and fifth threaded holes 32, 34 of a through type and set in the proximity of the bottom edge 25. In particular, the fourth threaded holes 32 are set so as to be aligned with respective first threaded holes 14 of the bottom plate 2.

As shown in FIG. 2, the frame 6 extends around the bottom printed-circuit board 4 and the bottom plate 2 in such a way that the bottom edge 25 is substantially aligned with the bottom surface S₂₁ of the bottom plate 2. In practice, the bottom printed-circuit board 4 is set between the bottom plate 2 and the frame 6, and is housed within the cavity 30 defined by the frame 6. Furthermore, the frame 6 is constrained to the bottom plate 2 by means of a plurality of second screws 36, which pass through the first and fourth threaded holes 14, 32.

As regards the top printed-circuit board 8, it comprises a second electronic circuit 38, which is illustrated schematically in FIG. 1 and is formed by a plurality of second electronic components 39, which are also illustrated schematically. In addition, the top printed-circuit board 8 comprises a plurality of sixth threaded holes 40 of a through type, top connectors 42, and second internal connectors 43. In particular, the second internal connectors 43 are set on a bottom surface S₈₁ of the top printed-circuit board 8 facing the bottom printed-circuit board 4; instead, the top connectors 42 are set on a top surface S₈₂ of the top printed-circuit board 8 opposite to the bottom surface S₈₁.

The top shell 10, made for example of metal material, has a concave shape and has a plurality of seventh, eighth, and ninth threaded holes 44, 46 and 48; the eighth threaded holes 46 are of a through type, whereas the seventh and ninth threaded holes 44, 48 are of a blind type. Furthermore, the top shell 10 has a top opening 50.

In detail, the seventh threaded holes 44 of the top shell 10 are set so as to be aligned to the sixth threaded holes 40 of the top printed-circuit board 8, whereas the eighth threaded holes 46 of the top shell 10 are set so as to be aligned to the fifth threaded holes 34 of the frame 6. In addition, the ninth threaded holes 48 are set so as to be aligned to the fourth threaded holes 32 of the frame 6 and to the first threaded holes 14 of the bottom plate 2.

As shown in FIG. 2, the top printed-circuit board 8 is housed within the cavity 30 defined by the frame 6, which in turn is housed partially within the concavity of the top shell 10. Also the top printed-circuit board 8 is housed within the concavity of the top shell 10, and is set in such a way that the top connectors 42 extend through the top opening 50 of the top shell 10. Furthermore, the bottom printed-circuit board 4, the top printed-circuit board 8, the first internal connectors 23, and the second internal connectors 43 are set in such a way that the first and second internal connectors 23, 43 are coupled to one another, thus electrically connecting the first electronic circuit 18 and the second electronic circuit 38.

The top printed-circuit board 8 is moreover constrained to the top shell 10 by means of a plurality of third screws 52, which pass through the sixth and seventh threaded holes 40, 44. In turn, the top shell 10 is constrained to the frame 6 by means of a plurality of fourth screws 54, which pass through the fifth and eighth threaded holes 34, 46. Furthermore, the second screws 36 pass not only through the first and fourth threaded holes 14, 32, but also through the ninth threaded holes 48 of the top shell 10, in a way such as to couple mechanically the top shell 10, the frame 6, and the bottom plate 2.

In practice, the electronic device 1 is enclosed by the top shell 10 and by the bottom plate 2, which functions, together with the frame 6, as bottom shell.

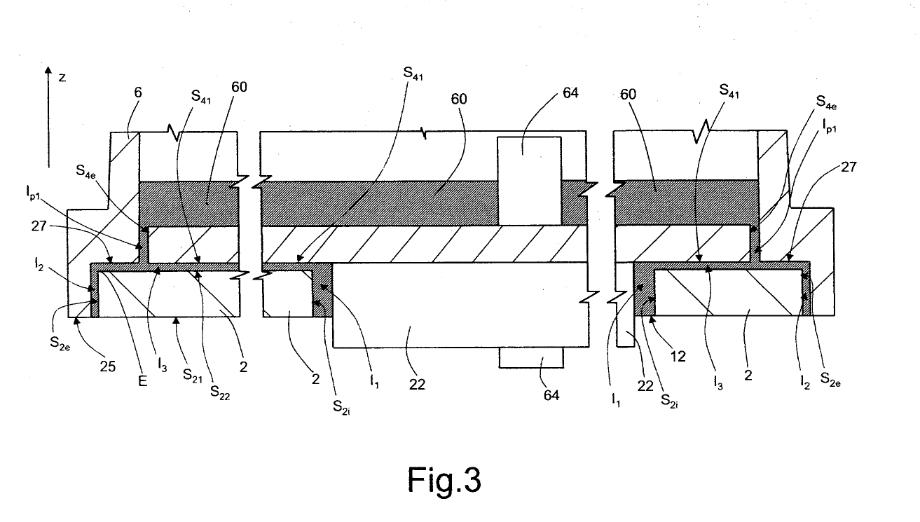

In greater detail, as shown in FIG. 3, the bottom plate 2, the bottom printed-circuit board 4, and the frame 6 are coupled in such a way as to form a first joining region, which is formed by a first gap I₁ and a second gap I₂.

In particular, the first gap I₁ is formed by the bottom-opening portion 12 not occupied by the bottom connectors 22. Consequently, designating by S₂ᵢ an internal surface of the bottom plate 2 that delimits the bottom opening 12, the first gap I₁ is delimited by the internal surface S₂ᵢ and by the bottom connectors 22.

The second gap I₂ is delimited by the lateral surface S₂ₑ of the bottom plate 2 and by the frame 6. Furthermore, the first gap I₁ and the second gap I₂ are connected by a third gap I₃, which is delimited by the bottom surface S₄₁ of the bottom printed-circuit board 4, by the shoulder 27, and by the top surface S₂₂ of the bottom plate 2.

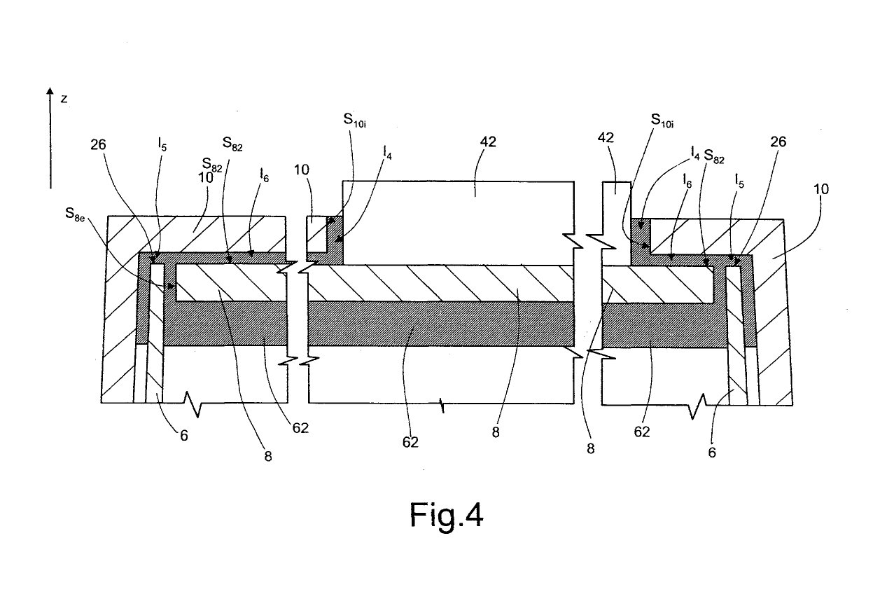

In greater detail, as shown in FIG. 4, the frame 6, the top printed-circuit board 8, and the top shell 10 are coupled in such a way as to form a second joining region, which is formed by a fourth gap I₄ and a fifth gap I₅.

In particular, the fourth gap I₄ is formed by the top-opening portion 50 not occupied by the top connectors 42; consequently, designating by S₁₀ᵢ an internal surface of the top shell 10 that delimits the top opening 42, the fourth gap I₄ is delimited by the internal surface S₁₀ᵢ and by the top connectors 42.

The fifth gap I₅ is delimited by the top edge 26 of the frame 6 and by the portion of top shell 10 facing the top edge 26. In addition, the fourth gap I₄ and the fifth gap I₅ are connected by a sixth gap I₆, which is delimited by the top surface S₈₂ of the top printed-circuit board 8 and by the top shell 10.

As shown in FIGS. 3 and 4, to ensure liquid-tightness of the electronic device 1, it is possible to close hermetically, i.e., in a liquid-tight manner, the first and second joining regions. The hermetic closing of the first and second joining regions is guaranteed, respectively, by a first layer of hardened resin and a second layer of hardened resin, which are impermeable.

As shown in FIGS. 2 and 3, the first layer of hardened resin, designated by 60, extends on top of, and in direct contact with, the bottom printed-circuit board 4, as well as into the first, second, and third gaps I₁, I₂ and I₃. Furthermore, the first layer of hardened resin 60 extends into a penetration gap Iₚ₁ (FIG. 3) delimited by a lateral surface S₄ₑ of the bottom printed-circuit board 4 and by the frame 6.

As shown in FIGS. 2 and 4, the second layer of hardened resin, designated by 62, extends underneath, and in direct contact with, the top printed-circuit board 8, as well as within the fourth, fifth, and sixth gaps I₄, I₅ and I₆.

By way of example, the resin that forms the first and second layers of hardened resin 60, 62 can be a silicone resin, or else an epoxy resin, or else a polyurethane resin. In practice, the first and second layers of hardened resin 60, 62 can be made of any resin that, after a hardening process, is impermeable.

In what follows it is assumed that the first and second layers of hardened resin 60, 62 are formed by a thermosetting resin, which, if subjected to thermal treatment, can change from the liquid state to the solid state; in greater detail, the thermal treatment causes the thermosetting resin to polymerize, and in particular to crosslink, thus hardening.

As shown in FIGS. 1 and 2, the electronic device 1 further comprises a tube 64 made of plastic material (for example, polybutylene terephthalate), which is fixed to the bottom printed-circuit board 4 and traverses the first layer of hardened resin 60, as well as the bottom printed-circuit board 4 itself. Furthermore, the tube 64 extends through the bottom opening 12 in such a way that it sets in communication the space underlying the bottom plate 2 with a portion of cavity 30 comprised between the top printed-circuit board 8 and the bottom printed-circuit board 4, and not occupied either by the first layer of hardened resin 60 or by the second layer of hardened resin 62. The function performed by the tube 64 is described in what follows.

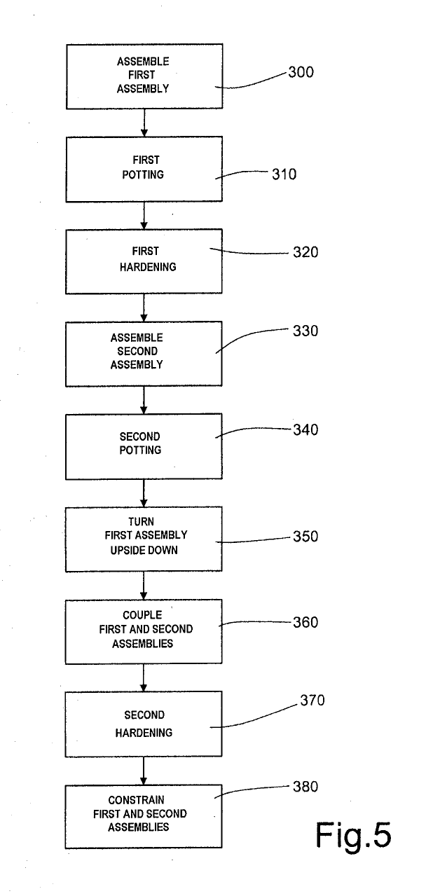

In order to manufacture the electronic device 1 it is possible to carry out the operations shown in FIG. 5.

In particular, once the bottom plate 2, the bottom printed-circuit board 4, the frame 6, the top printed-circuit board 8, and the top shell 10 are available, the bottom plate 2, the bottom printed-circuit board 4, and the frame 6 are assembled (block 300) in such a way as to form a first assembly, shown in FIG. 6 and designated by 70.

In detail, to assemble the first assembly 70, the bottom printed-circuit board 4 is mechanically coupled to the bottom plate 2 using the first screws 24, and the frame 6 is then mechanically coupled to the bottom plate 2 using the second screws 36. In greater detail, except where otherwise specified, in what follows it is assumed that, during the operations represented in FIG. 5, the bottom plate 2, the bottom printed-circuit board 4, and the frame 6, as well as the top printed-circuit board 8 and the top shell 10, are set as illustrated in FIG. 1, where a reference axis z is shown. In other words, with reference, for example, to the first assembly 70, it is assumed that it will be assembled so that the bottom surface S₂₁ of the bottom plate 2 is the lowest point of the first assembly 70 with respect to the axis z.

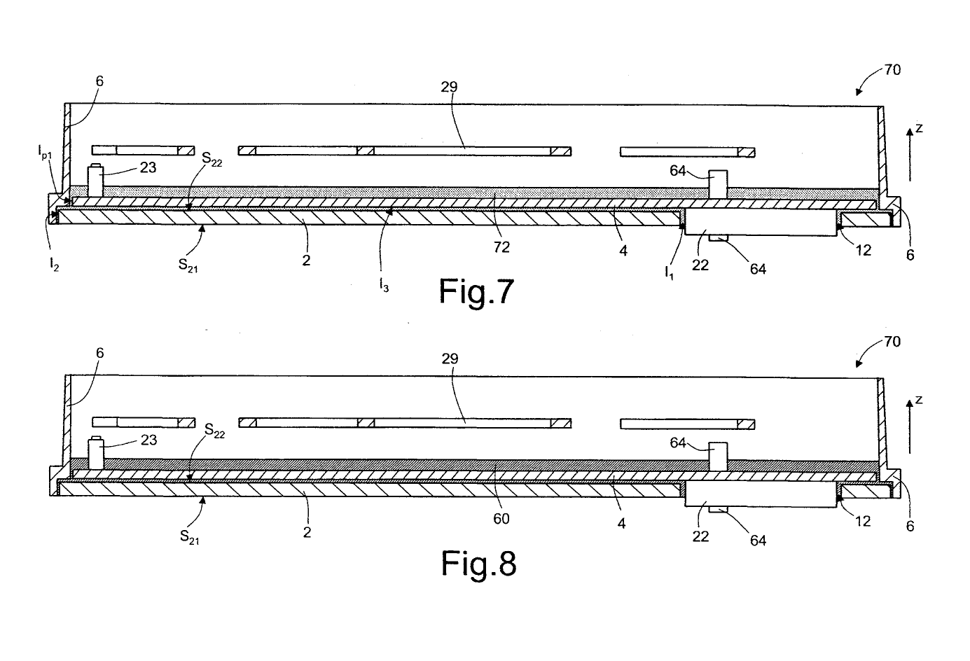

Next, as shown in FIG. 7, a first potting is carried out (block 310) by depositing a first layer of liquid resin 72 in the first assembly 70. The first potting is obtained by means of injection of resin from the top down (with respect to the axis z); consequently, during the process of injection, the resin encounters first the frame 6, then the bottom printed-circuit board 4, and finally the bottom plate 2.

In detail, during the first potting, the resin penetrates into the first penetration gap Iₚ₁ and then penetrates into the first, second, and third gaps I₁, I₂, I₃, filling the first joining region. Consequently, at the end of the first potting, the bottom printed-circuit board 4 is immersed in the first layer of liquid resin 72, which moreover extends into the first penetration gap Iₚ₁, and into the first, second, and third gaps I₁, I₂, I₃. In practice, filling of the first joining region by the resin is obtained thanks to the action of the force of gravity and the hydraulic pressure to which the resin is subject in the area corresponding to the first and second gaps I₁ and I₂.

Next, as shown in FIG. 8, a first hardening process is carried out (block 320), for example by subjecting the first assembly 70 to a thermal treatment at 50° C. for the duration of sixty minutes, in such a way that the first layer of liquid resin 72 is transformed into the first layer of hardened resin 60, obtained by means of cross-linking of the resin.

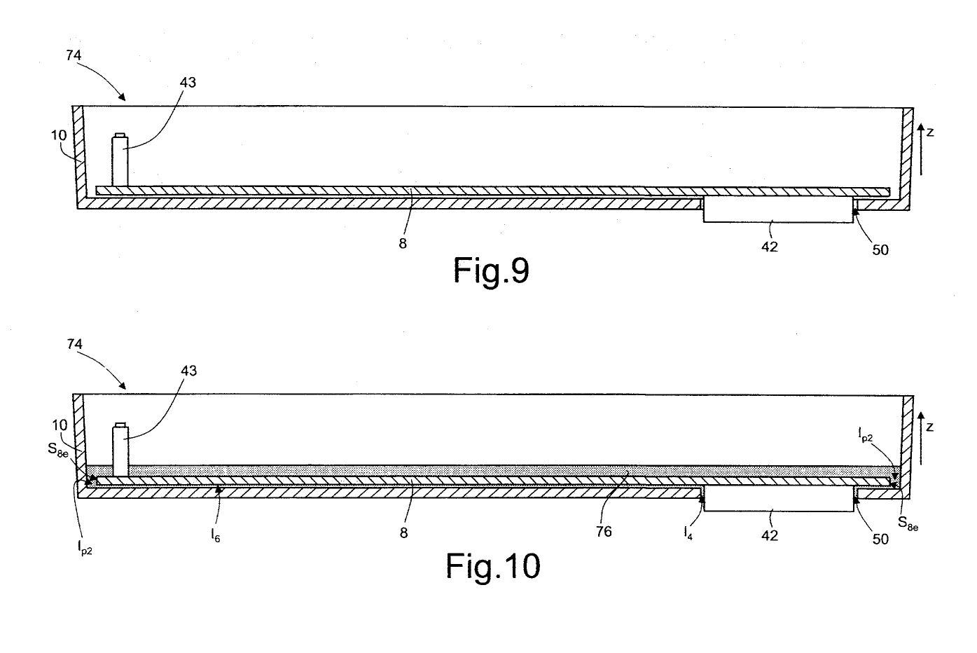

Next, the top printed-circuit board 8 and the top shell 10 are assembled (block 330), in such a way as to create a second assembly, shown in FIG. 9 and designated by 74. In particular, in order to assemble the second assembly 74, the top printed-circuit board 8 can be mechanically coupled to the top shell 10 by arranging the top shell 10 so that the respective concavity faces upwards (with respect to the axis z), inserting the top printed-circuit board 8 within the concavity of the top shell 10, and finally screwing the third screws 52. In practice, at the end of the operations of block 330, the second assembly 74 is set with the top shell 10 underneath the top printed-circuit board 8.

Next, without modifying the arrangement of the second assembly 74, a second potting is carried out (block 340), depositing within the second assembly 74 a second layer of liquid resin 76, shown in FIG. 10. The second potting is performed by means of injection of resin from the top down (with respect to the axis z). Consequently, during the second potting, the resin penetrates into a second penetration gap Iₚ₂, delimited by a lateral surface S₈ₑ of the top printed-circuit board 8 and by the top shell 10 and then penetrates into the fourth and sixth gaps I₄, I₆. At the end of the second potting, the top printed-circuit board 8 is immersed in the second layer of liquid resin 76. In practice, also the second layer of liquid resin 76 forms under the action of the force of gravity and the hydraulic pressure to which the resin itself is subjected, in particular in the area corresponding to the fourth gap I₄.

Next, the electronic device 1 is assembled by mechanically coupling the first and second assemblies 70, 74.

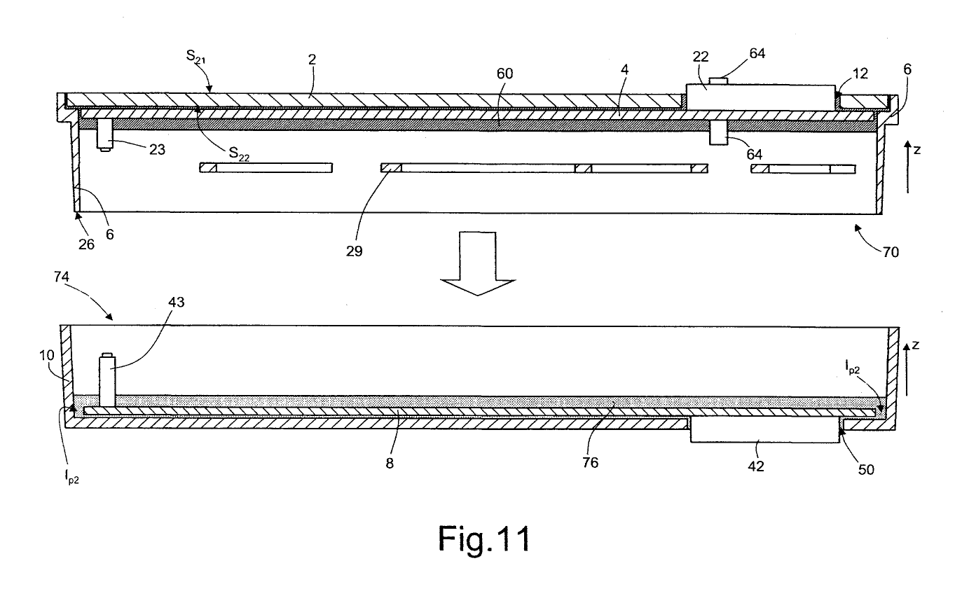

As shown in FIG. 11, to assemble the electronic device 1, the first assembly 70 is turned upside down (block 350) so that the bottom surface S₂₁ of the bottom plate 2 is set facing upwards (with respect to the axis z).

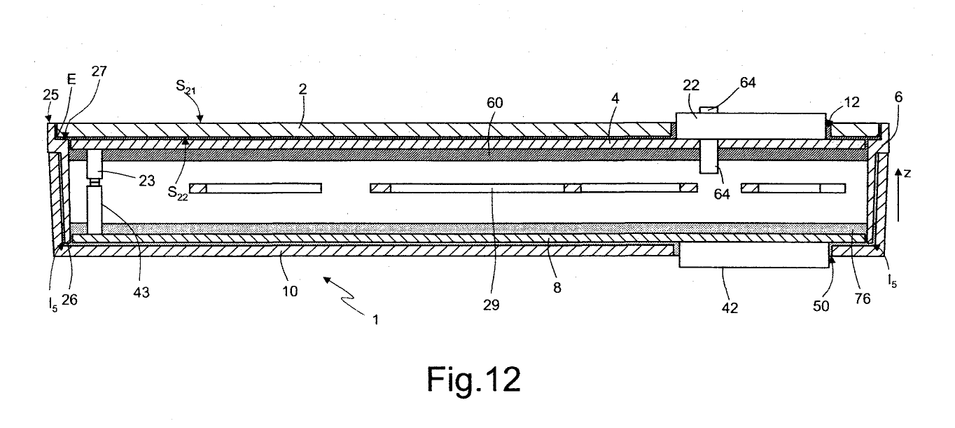

Next, the first assembly 70, thus turned upside down, and the second assembly 74 are coupled together (block 360). In particular, the first assembly 70 is inserted within the concavity of the top shell 10, on top of the top printed-circuit board 8, and in such a way that, as shown in FIG. 12, the top edge 26 of the frame 6 is inserted within the second penetration gap Iₚ₂. In this way, the fifth gap I₅ is formed, which is filled by the second layer of liquid resin 76. Consequently, also the second joining region is filled by the second layer of liquid resin 76.

During the operations of block 360, the presence of the tube 64 enables relief of any gas possibly present within the cavity 30 so as to enable the effective coupling of the first and second assemblies 70, 74.

A second hardening process is then carried out (block 370), for example by subjecting the electronic device 1 to a thermal treatment at 50° C. for the duration of sixty minutes in such a way that the second layer of liquid resin 76 is transformed into the second layer of hardened resin 62, obtained by means of cross-linking of the resin.

Finally, the first and second assemblies 70, 74 are constrained together (block 380) by screwing the second screws 36 so that they pass also through the ninth threaded holes 48 and by screwing the fourth screws 54 so that they pass through the fifth and eighth threaded holes 34, 46.

In practice, the first and second layers of hardened resin 60, 62 close hermetically the first and second joining regions, and in particular the first, second, fourth, and fifth gaps I₁, I₂, I₄, I₅. In this way, the first and second layers of hardened resin 60, 62 prevent the contact of possible liquids with the first and second electronic circuitries 18, 38.

The liquid-tightness of the bottom connectors 22 and of the top connectors 42, as well as of the portion of tube 64 that extends on the outside of the electronic device 1, can be obtained, in a way in itself known, during a subsequent step of assembly of the electronic device 1 with further electronic apparatuses, external with respect to the electronic device 1.

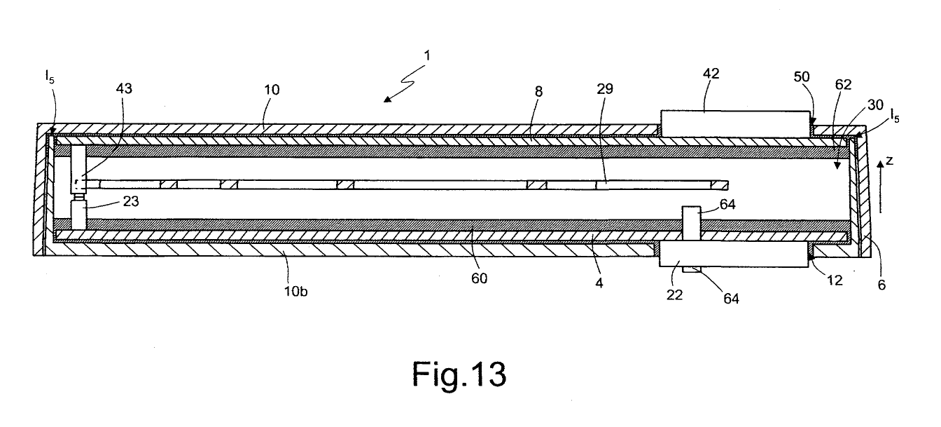

By way of example, FIG. 13 shows a different embodiment of the electronic device 1, present in which, instead of the bottom plate 2 and of the frame 6, is a bottom shell 10b, which has a concave shape and is made of a pressure-formable material, such as for example aluminum. In detail, as compared to what has been described previously, the electronic device 1 is without the second gap I₂, whilst the fifth gap I₅ is delimited by the top shell 10 and by the bottom shell 10b.

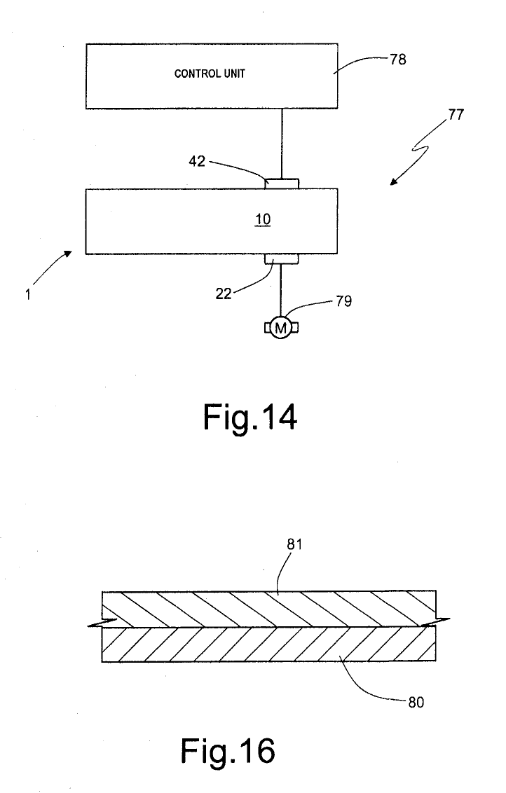

FIG. 14 shows, instead, a possible electronic system 77 comprising the electronic device 1, a control unit 78, and an electrical apparatus, in the case in point an electric motor 79. In detail, the control unit 78 is connected to the top connectors 42 of the electronic device 1, the bottom connectors of which 22 are connected to the electric motor 79.

From a practical standpoint, the bottom plate 2 operates as a dissipator; consequently, the electronic device 1 can be set in such a way that the bottom plate 2 faces a heat source, such as for example the electric motor 79. Possibly, the bottom plate 2 may be in contact with this heat source.

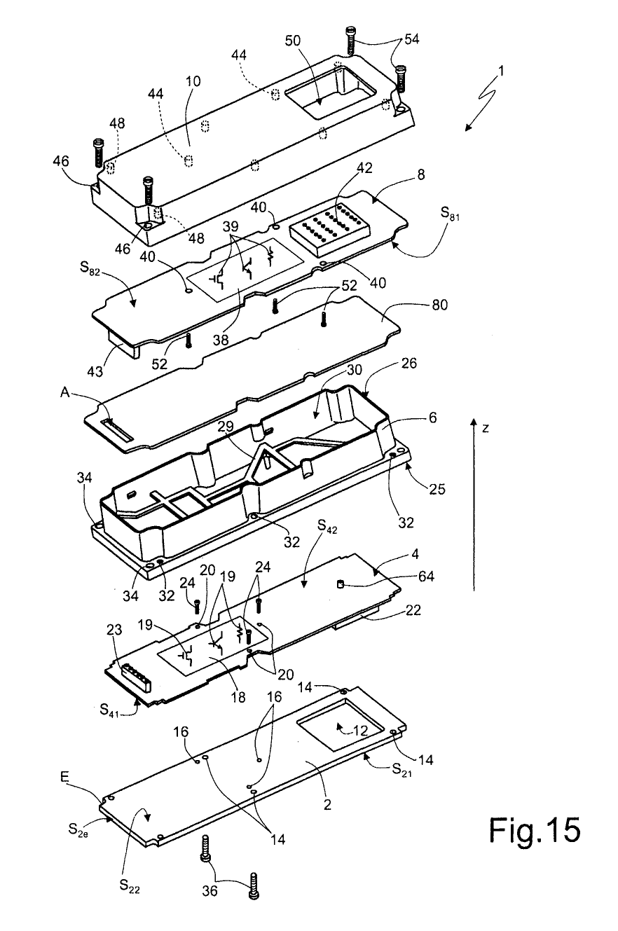

As shown in FIG. 15, the electronic device 1 can moreover comprise a thermal shield 80, formed by a layer made of thermally insulating material, such as for example ceramic paper, and carried by the frame 6 so as to be set between the bottom printed-circuit board 4 and the top printed-circuit board 8.

In particular, the thermal shield 80 can be carried by the supporting elements 29 of the frame 6, and has an opening A, which enables coupling together of the first and second internal connectors 23, 43. In the case where the electronic device 1 comprises, instead of the frame 6 and of the bottom plate 2, the bottom shell 10b, the thermal shield can be constrained to the bottom shell 10b. Furthermore, as shown in FIG. 16, the thermal shield 80 can be integrated with an electromagnetic shield 81, in itself known.

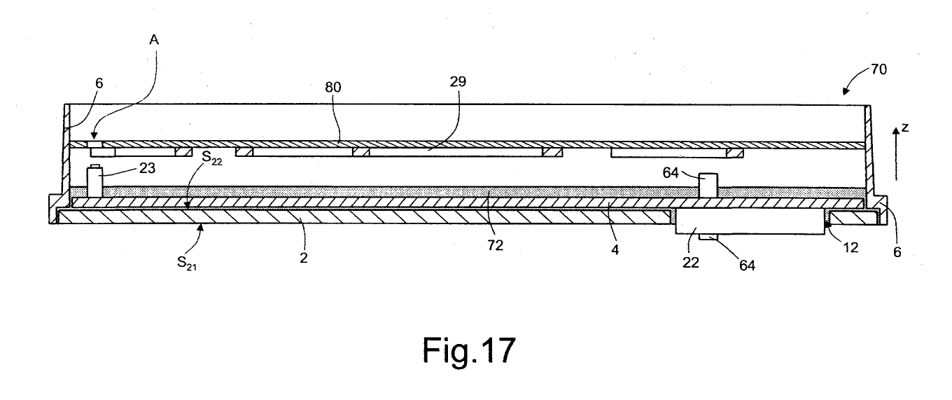

With reference to the operations represented in FIG. 5, the thermal shield 80 can be mounted in the first assembly 70, by means of slotting with the supporting elements 29 of the frame 6, for example after carrying out the first potting (block 310), or else after carrying out the first hardening process (block 320). In particular, in the case where the thermal shield 80 is mounted immediately after carrying out the first potting, the first assembly 70 assumes the shape shown in FIG. 17.

Furthermore, if the electronic device 1 performs a whole set of functions, such as for example functions of driving of a load, signal-processing functions, supply functions, etc., it is possible to distinguish, within the set of functions, a first subset of functions, which can be performed by corresponding first circuits formed by electronic components of a first type, and a second subset of functions, which can only be performed by corresponding second circuits formed by electronic components of a second type.

In detail, given a generic electronic component, it is possible to distinguish whether said generic electronic component is an electronic component of the first type or else of the second type, according to the respective maximum operating temperature. In particular, an electronic component of the first type is an electronic component that has a maximum operating temperature higher than a first reference temperature T₁. Instead, an electronic component of the second type is an electronic component having a maximum operating temperature lower than a second reference temperature T₂, which is at the most equal to the first reference temperature T₁.

Assuming purely by way of example that T₁=125° C. and T₂=85° C., components such as for example insulated-gate bipolar transistors (IGBTs), field-effect transistors (FETs), and driver circuits are typically electronic components of the first type. Instead, and once again by way of example, microprocessors, memories, and so-called field programmable gate arrays (FPGAs) are typically electronic components of the second type.

Given these premises, it is possible to design the electronic device 1 so that the functions of the first and second subsets of functions are respectively performed by the first and second electronic circuits 18, 38, which consequently function respectively as power circuitry and as control circuitry.

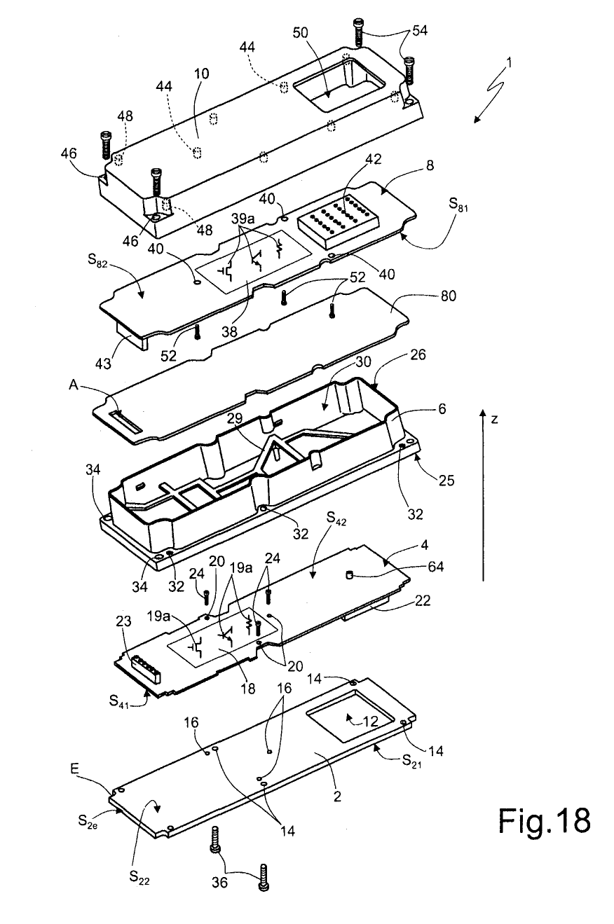

As shown in FIG. 18, it is hence possible to produce the first electronic circuit 18 so that it is formed by electronic components of the first type, designated by 19a. Furthermore, it is possible to produce the second electronic circuit 38 so that it is formed by electronic components of the second type, designated by 39a.

In this way, the electronic device 1 is particularly suited to operating also in the proximity of heat sources. In fact, by arranging the electronic device 1 so that a generic heat source is set underneath the bottom plate 2, the bottom plate 2 is set between the bottom printed-circuit board 4 and the heat source; however, since the first electronic circuit 18 is formed by the electronic components of the first type 19a, the closeness of the heat source to the first electronic circuit 18 is not harmful for operation of the electronic device 1. Instead, the thermal shield 80 is set between the top printed-circuit board 8 and the heat source, and protects the electronic components of the second type 39a of the second electronic circuit 38 from the heat source.

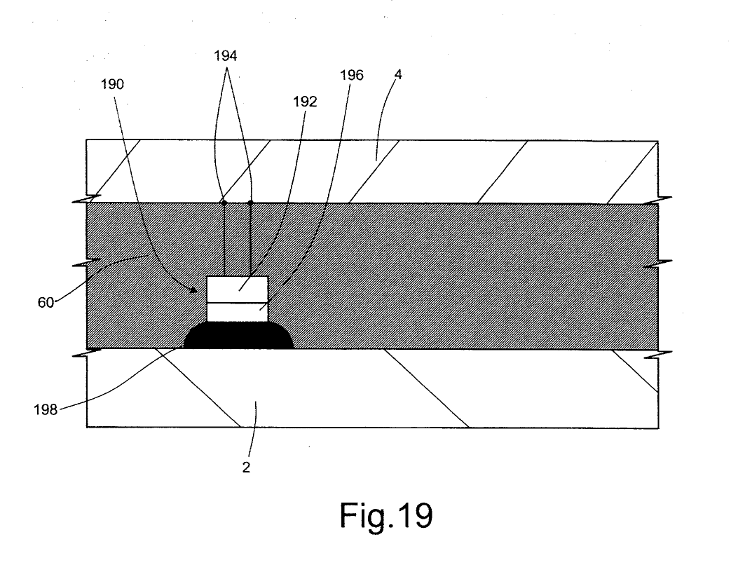

It is moreover possible to arrange the electronic components of the first type 19a of the bottom printed-circuit board 4 in the way illustrated in FIG. 19, which shows, by way of example, a power device 190, which is an electronic component of the first type.

In detail, the power device 190 comprises a casing 192, which is connected to the bottom printed-circuit board 4 by means of two terminals 194. Furthermore, the power device 190 comprises a substrate 196, made, for example, of ceramic material and connected to the casing 194. In addition, the substrate 196 is connected to the bottom plate 2 by means of a layer of soldering paste 198, in order to increase the thermal dissipation of the power device 190 itself. In this embodiment, the bottom plate 2 can be made of a material having a coefficient of thermal expansion similar to the coefficient of thermal expansion of the material forming the substrate 196.

In practice, operation of the electronic device 1 is not appreciably affected by heat sources. In addition, since the bottom printed-circuit board 4 and the top printed-circuit board 8 are set on top of one another, it is possible to resort to a thermal shield 80 having a smaller area, which shields from the heat source only the electronic components that are effectively sensitive to the heat sources, consequently limiting the additional costs due to the thermal shield 80 itself.

The advantages that the manufacturing method and present electronic device described herein afford emerge clearly from the above discussion.

In particular, since no gaskets are used, the electronic devices obtained by means of the present method are less subject to ageing and degradation due to thermal stresses. Furthermore, the first and second layers of hardened resin 60, 62 protect the first and second electronic circuitries 18, 38 also from polluting agents. Again, the use of the resin, instead of the gaskets, means that the electronic device 1 can be immediately tested, since proper assembly thereof involves the fact that the resin does not drip in areas other than the areas in which its presence is in actual fact envisaged.

Finally, it is evident that modifications and variations may be made to the present manufacturing method and electronic device, without thereby departing from the scope of the present disclosure.

In particular, the arrangement and number of threaded holes, as well as of the screws, may be different from what is shown. Likewise, the geometrical shapes of the bottom plate 2, of the frame 6, the top shell 10, and the bottom shell 10b may be different from what is shown; consequently, also the mechanical couplings, and consequently also the first and second joining regions, may be different from what is described and shown.

For example, it is possible for the bottom printed-circuit board 4 not to be constrained to, but rather rest upon, the bottom plate 2, or else the bottom shell 10b. In this case, the bottom printed-circuit board 4 is held in position, for example, by the first layer of hardened resin 60. Likewise, it is possible for the top printed-circuit board 8 to rest on the top shell 10, and be held in position, for example, by the second layer of hardened resin 62. Also the thermal shield 80 may not be constrained to, but rather rest on, the supporting elements 29 of the frame 6.

It is moreover possible for the bottom printed-circuit board 4 and the top printed-circuit board 8 to be constrained, respectively, to the bottom plate 2 and to the top shell 10 by means of welding, instead of by means of screwing.

It is likewise possible for the bottom printed-circuit board 4 or else for the top printed-circuit board 8 to be absent.

Finally, some of the operations of blocks 300-380 can be carried out in a different order with respect to what is described and shown in FIG. 5.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A method, comprising:
manufacturing a liquid-tight electronic device, the manufacturing including:
providing a first printed-circuit board that includes a first connector;
providing a supporting structure that includes a first opening;
forming a first assembly by coupling said supporting structure and said first printed-circuit board in such a way that said first connector extends through said first opening, said first connector and said supporting structure delimiting a bottom gap; and
forming a second assembly that includes a protective shell;
potting the first assembly by depositing a first layer of liquid resin within said first assembly, the potting causing said first layer of liquid resin to penetrate into said bottom gap;
forming a first layer of hardened resin by hardening said first layer of liquid resin;
potting the second assembly by depositing a second layer of liquid resin within said second assembly;
coupling said first and second assemblies while the second layer of liquid resin is still fluid in such a way that the second layer of liquid resin hermetically closes a first interstitial area between the protective shell and the supporting structure; and
forming a second layer of hardened resin by hardening said second layer of liquid resin after coupling said first and second assemblies.

2. The method according to claim 1, wherein said protective shell comprises a second opening, and further comprising:
providing a second printed-circuit board that includes a second connector; wherein:
forming the second assembly comprises coupling said protective shell and said second printed-circuit board in such a way that said second connector extends through said second opening, said second connector and said protective shell delimiting a top gap; and
potting the second assembly comprises causing said second layer of liquid resin to penetrate into said top gap, hermetically closing said top gap.

3. The method according to claim 2, wherein said supporting structure comprises a frame and a plate, said plate defining said first opening and delimiting said bottom gap; and wherein forming the first assembly comprises setting said first printed-circuit board between said plate and said frame, said plate and said frame delimiting a second interstitial area.

4. The method according to claim 3, wherein potting the first assembly comprises causing said first layer of liquid resin to penetrate into said second interstitial area, hermetically closing said second interstitial area.

5. The method according to claim 3, wherein coupling said first and second assemblies comprises coupling said first and second assemblies in such a way that said first interstitial area is delimited by said top shell and by said frame.

6. The method according to claim 2, wherein said supporting structure comprises a bottom shell, made of pressure-formable material, defining said first opening and delimiting said bottom gap; and wherein coupling said first and second assemblies comprises delimiting said first interstitial area by said protective shell and by said bottom shell.

7. The method according to claim 2, further comprising providing a thermal shield, made of thermally insulating material and set between said first printed-circuit board and said second printed-circuit board.

8. The method according to claim 2, further comprising:
setting, on the first printed-circuit board, a first electronic circuit formed by electronic components having respective maximum operating temperatures higher than a first reference temperature; and
setting, on the second printed-circuit board, a second electronic circuit formed by electronic components having respective maximum operating temperatures lower than a second reference temperature, said second reference temperature being lower than said first reference temperature.

9. A liquid-tight electronic device, comprising:
a first assembly including a first printed-circuit board and a supporting structure, said first printed-circuit board including a first connector, said supporting structure including a first opening, said first printed-circuit board and said supporting structure being coupled in such a way that said first connector extends through said first opening, said first connector and said supporting structure delimiting a bottom gap;
a second assembly that includes a protective shell and is coupled to said first assembly, the protective shell and the supporting structure delimiting a first interstitial area;
a first layer of hardened resin that extends within said bottom gap; and
a second layer of hardened resin that hermetically closes said first interstitial area.

10. The liquid-tight electronic device according to claim 9, wherein said protective shell comprises a second opening, and wherein said second assembly further includes a second printed-circuit board having a second connector and being coupled to said protective shell in such a way that said second connector extends through said second opening, said second connector and said protective shell delimiting a top gap, said second layer of hardened resin extending within said top gap.

11. The liquid-tight electronic device according to claim 10, wherein said supporting structure comprises a frame and a plate, said plate defining said first opening and delimiting said bottom gap; and wherein said first printed-circuit board is set between said plate and said frame, said plate and said frame delimiting a second interstitial area.

12. The liquid-tight electronic device according to claim 11, wherein said first layer of hardened resin extends within said second interstitial area, hermetically closing said second interstitial area.

13. The liquid-tight electronic device according to claim 11, wherein said first and second assemblies are coupled in such a way that said first interstitial area is delimited by said top shell and by said frame.

14. The liquid-tight electronic device according to claim 10, wherein said supporting structure comprises a bottom shell made of pressure-formable material, defining said first opening and delimiting said bottom gap; and wherein said first and second assemblies are coupled in such a way that said first interstitial area is delimited by said protective shell and by said bottom shell.

15. The liquid-tight electronic device according to claim 10, further comprising a thermal shield made of thermally insulating material and set between said first and second printed-circuit boards.

16. The liquid-tight electronic device according to claim 10, wherein said first printed-circuit board houses a first electronic circuit formed by electronic components having respective maximum operating temperatures higher than a first reference temperature; and wherein said second printed-circuit board houses a second electronic circuit formed by electronic components having respective maximum operating temperatures lower than a second reference temperature, said second reference temperature being lower than said first reference temperature.

17. The liquid-tight electronic device according to claim 9, wherein said supporting structure defines a cavity, and further comprising a passage configured to couple said cavity with the outside of the electronic device.

18. An electronic system comprising:
a control unit;
an electrical apparatus; and
a liquid-tight electronic device that includes:
a first assembly including a first printed-circuit board and a supporting structure, said first printed-circuit board including a first connector, said supporting structure including a first opening, said first printed-circuit board and said supporting structure being coupled in such a way that said first connector extends through said first opening, said first connector and said supporting structure delimiting a bottom gap;
a second assembly that includes a protective shell and is coupled to said first assembly, the protective shell and the supporting structure delimiting a first interstitial area;
a first layer of hardened resin that extends within said bottom gap; and
a second layer of hardened resin that hermetically closes said first interstitial area.

19. The electronic system according to claim 18, wherein said protective shell comprises a second opening, and wherein said second assembly further includes a second printed-circuit board having a second connector and being coupled to said protective shell in such a way that said second connector extends through said second opening, said second connector and said protective shell delimiting a top gap, said second layer of hardened resin extending within said top gap.

20. The electronic system according to claim 19, wherein said supporting structure comprises a frame and a plate, said plate defining said first opening and delimiting said bottom gap; and wherein said first printed-circuit board is set between said plate and said frame, said plate and said frame delimiting a second interstitial area.

21. The electronic system according to claim 20, wherein said first layer of hardened resin extends within said second interstitial area, hermetically closing said second interstitial area.

22. The electronic system according to claim 20, wherein said first and second assemblies are coupled in such a way that said first interstitial area is delimited by said top shell and by said frame.

23. The electronic system according to claim 19, wherein said supporting structure comprises a bottom shell made of pressure-formable material, defining said first opening and delimiting said bottom gap; and wherein said first and second assemblies are coupled in such a way that said first interstitial area is delimited by said protective shell and by said bottom shell.

24. The electronic system according to claim 19, wherein the liquid-tight electronic device includes a thermal shield made of thermally insulating material and set between said first and second printed-circuit boards.

25. The electronic system according to claim 19, wherein said first printed-circuit board houses a first electronic circuit formed by electronic components having respective maximum operating temperatures higher than a first reference temperature; and wherein said second printed-circuit board houses a second electronic circuit formed by electronic components having respective maximum operating temperatures lower than a second reference temperature, said second reference temperature being lower than said first reference temperature.

26. The electronic system according to claim 18, wherein said supporting structure defines a cavity, and further comprising a passage configured to couple said cavity with the outside of the electronic device.
